(19) United States
(12) Patent Application Publication
(10) Pub. No.: US 2025/0143136 A1
(43) Pub. Date: May 1, 2025

(54) ELECTRODE, DISPLAY PANEL INCLUDING THE ELECTRODE, AND METHOD OF MANUFACTURING THE ELECTRODE

(71) Applicants: Samsung Display Co., Ltd., Yongin-si (KR); Seoul National University R&DB Foundation, Seoul (KR)

(72) Inventors: SEOLHYE PARK, Yongin-si (KR); Gon-Ho KIM, Seoul (KR); YOONA PARK, Yongin-si (KR); Namjae BAE, Seoul (KR); Haneul LEE, Seoul (KR)

(21) Appl. No.: 18/908,386

(22) Filed: Oct. 7, 2024

(30) Foreign Application Priority Data
Oct. 31, 2023 (KR) 10-2023-0148080

(51) Int. Cl. H10K 59/80; H10K 59/122; H10K 102/10

(52) U.S. Cl. CPC H10K 59/80517; H10K 59/122; H10K 2102/102; H10K 2102/103

(57) ABSTRACT

An electrode according to an embodiment of the present disclosure includes a first layer including a transparent conductive oxide containing indium. The first layer includes a first area and a second area surrounding at least a portion of the first area. The indium content of a surface of the first layer corresponding to the first area is greater than the indium content of a surface of the first layer corresponding to the second area.

This application claims priority to Korean Patent Application No. 10-2023-0148080, filed on Oct. 31, 2023, and all the benefits accruing therefrom under 35 U.S.C. § 119, the content of which in its entirety is herein incorporated by reference.

### BACKGROUND

The present disclosure herein relates to an electrode, a display panel including the electrode, and a method of manufacturing the electrode, and more particularly, to an electrode with improved manufacturing efficiency and manufacturing reliability, a display panel including the electrode, and a method of manufacturing the electrode.

Various electronic devices that can be worn on the body are being developed, and such devices may be referred to as wearable electronic devices. The wearable electronic devices may be of various forms and may be attachable to or detachable from parts of the human body or clothing. In an example, a wearable electronic device that can be mounted on a user's head may be referred to as, for example, a head-mounted device (HMD). In some cases, devices such as a HMD may require the formation of fine structures with ultra-high resolution of 3000 ppi (pixels per inch) or more.

### SUMMARY

An object of the present disclosure is to provide an electrode with improved manufacturing efficiency, while realizing high resolution, a display panel including the electrode, and a method of manufacturing the electrode.

An electrode according to an embodiment supported by the present disclosure includes a first layer including a transparent conductive oxide containing indium. The first layer includes a first area and a second area surrounding at least a portion of the first area. An indium content of a surface of the first layer corresponding to the first area is greater than an indium content of a surface of the first layer corresponding to the second area.

In an embodiment, the electrode according to an embodiment supported by the present disclosure may further include a metal layer that is disposed below the first layer and includes aluminum.

In an embodiment, the electrode according to an embodiment supported by the present disclosure may further include a second layer that is disposed between the metal layer and the first layer and includes aluminum oxide.

In an embodiment, the transparent conductive oxide may include indium tin oxide (ITO).

In an embodiment, a surface roughness of the surface of the first layer corresponding to the first area may be greater than a surface roughness of the surface of the first layer corresponding to the second area.

In an embodiment, the first area may include a plurality of first sub-areas spaced apart from each other.

In an embodiment, the second area may surround each of the plurality of first sub-areas.

In an embodiment, the first layer may be provided as a single layer composed of the transparent conductive oxide.

In an embodiment, a thickness of the first layer may range from about 2 nm to about 12 nm.

A display panel according to an embodiment supported by the present disclosure includes a pixel definition layer in which a light emitting element and a pixel opening are defined. The light emitting element includes a first electrode exposed through the pixel opening, a second electrode disposed on the first electrode, and at least one functional layer disposed between the first electrode and the second electrode. The first electrode includes a first layer including a transparent conductive oxide containing indium. A surface of the first layer includes a first area, and a second area surrounding at least a portion of the first area. An indium content of the first area is greater than an indium content of the second area.

In an embodiment, the first electrode may further include a metal layer that is disposed below the first layer and includes aluminum, and a second layer that is disposed between the metal layer and the first layer and includes aluminum oxide.

In an embodiment, the at least one functional layer may include a first emission layer emitting first light, and the at least one functional layer may include a second emission layer disposed on the first emission layer and emitting second light that is different from the first light.

In an embodiment, the light emitting element may include a first light emitting element, a second light emitting element, and a third light emitting element, spaced apart in a direction that is perpendicular to a thickness direction. The first light emitting element may emit red light, the second light emitting element may emit green light, and the third light emitting element may emit blue light.

A method of manufacturing an electrode according to an embodiment supported by the present disclosure includes forming a preliminary first layer including a transparent conductive oxide containing indium, forming a photoresist pattern on the preliminary first layer, where the photoresist pattern includes an opening part, and forming a first layer by etching the preliminary first layer using the photoresist pattern as a mask. The forming of the first layer includes a first step of providing first plasma including hydrogen (H₂) plasma on the preliminary first layer, and a second step of providing second plasma on the preliminary first layer, after the first step. The indium in the transparent conductive oxide agglomerates by the first plasma and forms an agglomeration pattern in the first step. Providing the second plasma in the second step etches the agglomeration pattern.

In an embodiment, each of the first step and the second step may be performed in plurality, and the plurality of the first steps and the plurality of the second steps may be performed alternately.

In an embodiment, a surface of the first layer may include a first area, and a second area surrounding at least a portion of the first area. An indium content of the first area may be greater than an indium content of the second area.

In an embodiment, the first area may correspond to an area where the agglomeration pattern is formed in the first step.

In an embodiment, the first step may include providing the first plasma for 30 seconds or more.

In an embodiment, the method of manufacturing an electrode according to an embodiment supported by the present disclosure may further include forming a preliminary metal layer including aluminum, prior to the forming of the preliminary first layer.

The preliminary first layer may be formed on the preliminary metal layer.

In an embodiment, the method of manufacturing an electrode according to an embodiment supported by the present disclosure may include etching the preliminary metal layer to form a metal layer, where the etching of the preliminary metal layer may be performed together with the etching of the preliminary first layer to form the first layer.

### BRIEF DESCRIPTION OF THE FIGURES

The accompanying drawings are included to provide a further understanding of aspects supported by the present disclosure and are incorporated in and constitute a part of this specification. The drawings illustrate embodiments of supported by aspects of the present disclosure and, together with the description, serve to explain principles supported by the present disclosure. In the drawings:

FIG. 1 is a perspective view of an electronic device according to an embodiment supported by the present disclosure;

FIG. 2 is a perspective view of an electronic device according to an embodiment supported by the present disclosure;

FIG. 3 is an exploded perspective view of an electronic device according to an embodiment supported by the present disclosure;

FIG. 4 is a cross-sectional view of a display panel according to an embodiment supported by the present disclosure;

FIG. 5 is a plan view illustrating a display panel according to an embodiment;

FIG. 6 is a cross-sectional view illustrating a display panel according to an embodiment;

FIG. 7A and FIG. 7B are enlarged cross-sectional views of a portion of the display panel according to an embodiment supported by the present disclosure;

FIG. 8A is a cross-sectional view of a partial configuration of a first electrode according to an embodiment supported by the present disclosure;

FIG. 8B is a plan view of a partial configuration of a first electrode according to an embodiment supported by the present disclosure;

FIG. 9 is a cross-sectional view illustrating a display panel according to an embodiment supported by the present disclosure;

FIG. 10A is a flowchart illustrating a method of manufacturing an electrode according to an embodiment supported by the present disclosure;

FIG. 10B is a flowchart illustrating some steps in the method of manufacturing an electrode according to an embodiment supported by the present disclosure;

FIG. 11A to FIG. 11C are cross-sectional views sequentially illustrating a method of manufacturing an electrode according to an embodiment supported by the present disclosure;

FIG. 12A to FIG. 12C are cross-sectional views illustrating some steps in a method of manufacturing an electrode according to an embodiment supported by the present disclosure;

FIG. 13A is a graph illustrating an agglomeration depth and the strain rate of a photoresist pattern in accordance with the hydrogen ion capacity of hydrogen plasma in some steps of the method of manufacturing an electrode according to an embodiment supported by the present disclosure;

FIG. 13B is a graph illustrating the strain rate of a photoresist pattern in accordance with the ion energy of argon plasma in some steps of the method of manufacturing an electrode according to an embodiment supported by the present disclosure;

FIG. 14A and FIG. 14B are microscope images illustrating the states of some steps in the method of manufacturing an electrode according to an embodiment supported by the present disclosure.

### DETAILED DESCRIPTION

In the description, when an element (or a region, a layer, a part, or the like) is referred to as being “on”, “connected with” or “combined with” another element, it can be directly disposed on/connected with/combined with the other element, or intervening third elements may also be disposed.

Like reference symbols refer to like elements throughout. In the drawings, the thicknesses, ratios, and dimensions of elements are exaggerated for effective explanation of technical contents. “and/or” may include one or more combinations that may define relevant elements.

It will be understood that, although the terms first, second, and the like may be used herein to describe various elements, these elements should not be limited by these terms. These terms are used to distinguish one element from another element. For example, a first element could be termed a second element without departing from the scope of the present invention. Similarly, a second element could be termed a first element. The singular forms are intended to include the plural forms as well, unless the context clearly indicates otherwise.

In some aspects, the terms “below”, “beneath”, “on” and “above” are used for explaining the relation of elements illustrated in the drawings. The terms are relative concept and are explained based on the direction illustrated in the drawings.

It will be further understood that the terms “comprises” or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

In the description, “directly disposed” may mean that there is no additional film, layer, area and plate between a part such as, for example, a film, layer, area and another part. For example, “directly disposed” may mean that two layers or two members are disposed without using an additional member such as, for example, an adhesive member therebetween.

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ±30%, 20%, 10%, 5% of the stated value, for example.

The term “substantially,” as used herein, means approximately or actually.

Unless otherwise defined, all terms (including technical and scientific terms) used herein have the same meaning as commonly understood by one of ordinary skill in the art to which the example embodiments described herein belong. In some aspects, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

Hereinafter, an electronic device according to an embodiment supported by the present disclosure and a display panel included therein will be explained referring to the drawings.

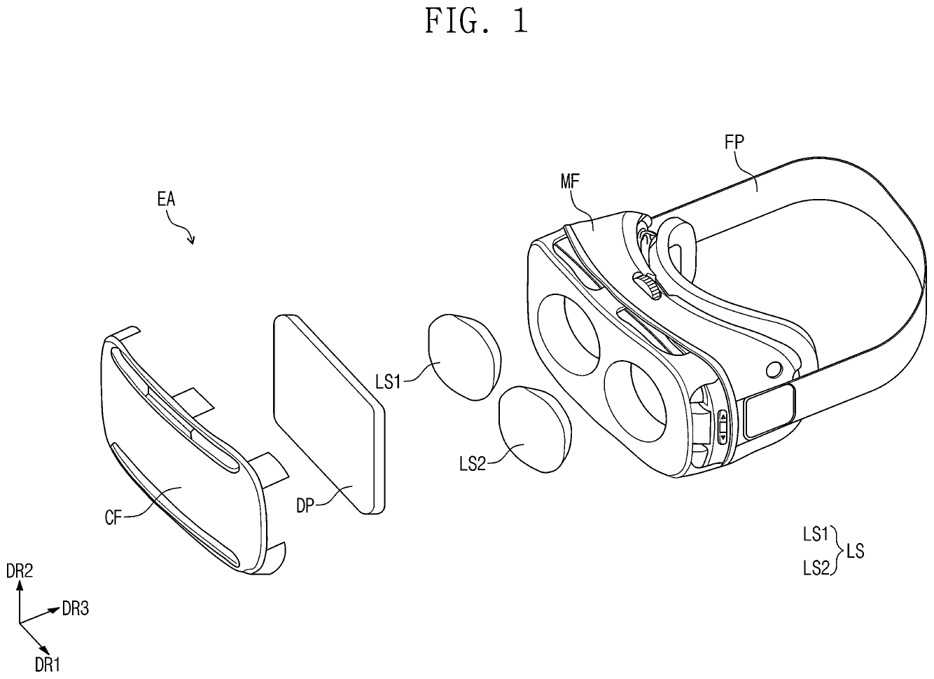

FIG. 1 is a perspective view illustrating an electronic device EA according to an embodiment supported by the present disclosure. The electronic device EA may be a device activated by electrical signals. Non-limiting examples of the electronic device EA may include televisions, monitors, external billboards, game consoles, personal computers, laptop computers, mobile phones, tablets, navigations, and wearable devices, but embodiments of the present disclosure are not limited thereto.

In FIG. 1, a head-mounted display (HMD) device is illustrated as an example of the electronic device EA. The head-mounted display device may be a device that is mounted on a user's head and provides a screen on which an image or video is displayed to the user. The head-mounted display device may be a see-through type that provides an augmented reality (AR) environment based on actual external objects, and a non-see-through type that provides a virtual reality (VR) environment to the user as a screen that is independent of external objects.

Referring to FIG. 1, the electronic device EA may include a display panel DP and a lens part LS facing the display panel DP. In some aspects, the electronic device EA may include a main frame MF, a cover frame CF, and a fixing part FP.

The main frame MF may be a part worn on the user's face. The main frame MF may have a shape corresponding to the shape of the user's head (face). For example, the length of the fixing part FP may be adjusted according to the circumference of the user's head. The fixing part FP is a structure that facilitates the mounting of the main frame MF and may include a strap, a belt, or the like. However, embodiments of the present disclosure are not limited thereto, and the fixing part FP may be of various forms such as, for example, a helmet and eyeglass temples, combined with the main frame MF.

A lens part LS, a display panel DP and a cover frame CF may be mounted on the main frame MF. The main frame MF may include a space or structure in which the lens part LS and the display panel DP may be accommodated.

The lens part LS may be disposed between the display panel DP and the user. The lens part LS may pass light emitted from the display penal DP and provide the light to the user. For example, the lens part LS may include various types of lenses including multi-channel lenses, convex lenses, concave lenses, spherical lenses, aspherical lenses, single lenses, composite lenses, standard lenses, narrow-angle lenses, wide-angle lenses, fixed-focus lenses, and variable-focus lenses.

The lens part LS may include a first lens LS1 and a second lens LS2. The first lens LS1 and the second lens LS2 may be disposed to correspond to the positions of the user's left and right eyes. The first lens LS1 and the second lens LS2 may be accommodated in the main frame MF.

The display panel DP may be provided in a fixed state to the main frame MF or in a detachable state. The display panel DP will be explained in more detail later.

The cover frame CF is disposed on one surface of the display panel DP and protect the display panel DP. The cover frame CF and the lens part LS may be spaced apart, with the display panel DP between the cover frame CF and the lens part LS.

In FIG. 1 and the following drawings, a first direction DR1 to a third direction DR3 are illustrated, and the directions indicated by the first to third directions DR1, DR2 and DR3 explained in the disclosure are relative concepts and may be converted to other directions. In some aspects, the directions indicated by the first to third directions DR1, DR2 and DR3 may be explained as the first to third directions, and the same reference symbols may be used. In the disclosure, the first direction DR1 and the second direction DR2 are orthogonal to each other, and the third direction DR3 is a normal direction to a plane defined by the first direction DR1 and the second direction DR2.

The thickness direction of the electronic device EA may be a direction parallel to the third direction DR3 that is the normal direction to the plane defined by the first direction DR1 and the second direction DR2. In the disclosure, the front surface (or top) and the rear surface (or bottom) of members constituting the electronic device EA may be defined based on the third direction DR3. In the disclosure, “on a plane” means a plane parallel to the plane defined by the first direction DR1 and the second direction DR2, and “on a cross section” means a plane parallel to the third direction DR3.

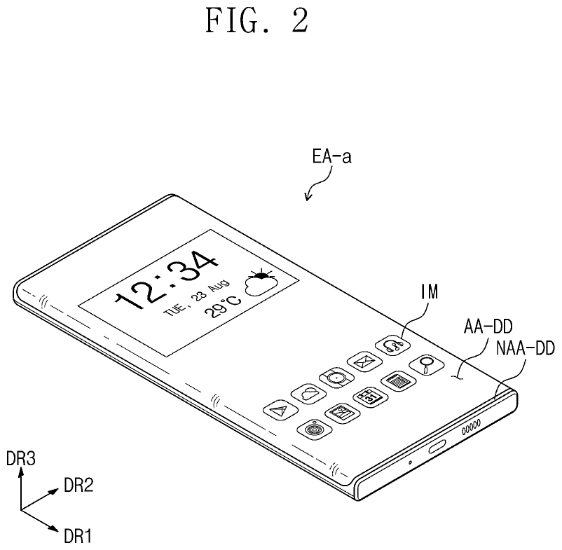

FIG. 2 is a perspective view of an electronic device EA-a according to an embodiment supported by the present disclosure. FIG. 2 is a perspective view illustrating another embodiment of the electronic device in accordance with one or more embodiments of the present disclosure, and a mobile phone is illustrated as an example of the electronic device EA-a. The electronic device EA-a may display an image IM through an active area AA-DD. The active area AA-DD may include a plane defined by the first direction DR1 and the second direction DR2. The active area AA-DD may include a curved surface bent from at least one side of a plane defined by the first direction DR1 and the second direction DR2. However, this is an example, and the shape of the active area AA-DD is not limited thereto. For example, the active area AA-DD may include the plane without including other surfaces, and the active area AA-DD may further include at least two curved surfaces, for example, four curved surfaces each bent from four sides of the plane.

A peripheral area NAA-DD is adjacent to the active area AA-DD. The peripheral area NAA-DD may surround the active area AA-DD. Accordingly, the shape of the active area AA-DD may be substantially defined by the peripheral area NAA-DD. However, this is an example illustration, and the peripheral area NAA-DD may be disposed adjacent to one side of the active area AA-DD or may be omitted. The active area AA-DD may be provided in various shapes, and is not limited to any one embodiment.

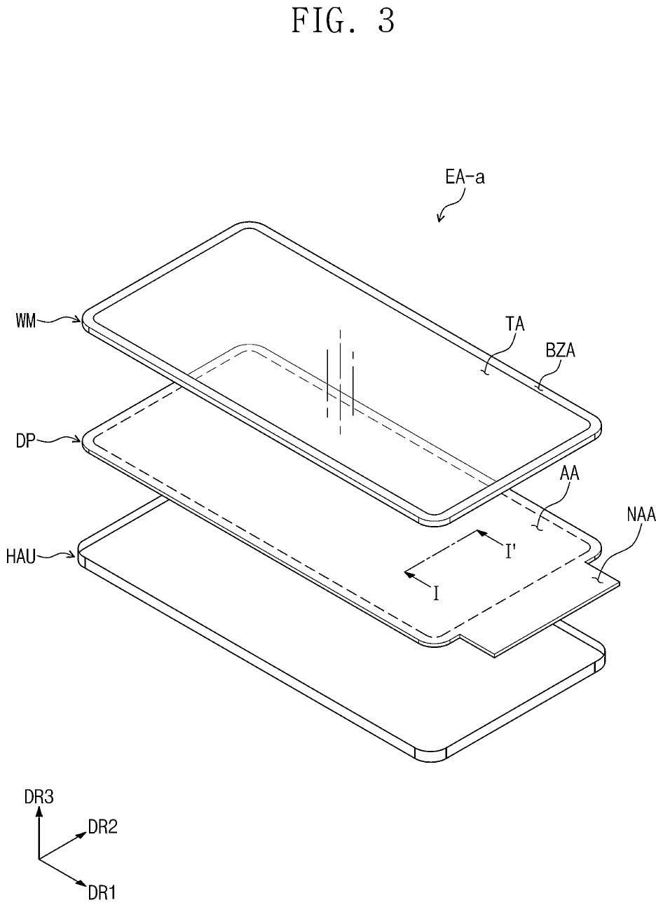

FIG. 3 is an exploded perspective view of an electronic device EA-a according to an embodiment supported by the present disclosure. FIG. 3 is an exploded perspective view of the electronic device EA-a illustrated in FIG. 2. Referring to FIG. 3, the electronic device EA-a may include a housing HAU, a display panel DP, and a window member WM.

The window member WM may cover the entire outside of the display panel DP. The window member WM may include a transmission area TA and a bezel area BZA. The front surface of the window member WM including the transmission area TA and the bezel area BZA may correspond to the front surface of the electronic device EA-a. The transmission area TA may correspond to the active area AA-DD of the electronic device EA-a illustrated in FIG. 2, and the bezel area BZA may correspond to the peripheral area NAA-DD of the electronic device EA-a illustrated in FIG. 2.

The transmission area TA may be an optically transparent area. The bezel area BZA may be an area having relatively low light transmittance compared to the transmission area TA. The bezel area BZA may have a certain color. The bezel area BZA may be adjacent to the transmission area TA and may surround the transmission area TA. The bezel area BZA may define the shape of the transmission area TA. However, embodiments of the present disclosure are not limited thereto, and the bezel area BZA may be disposed adjacent to a single side of the transmission area TA, or a portion of the bezel area BZA may be omitted.

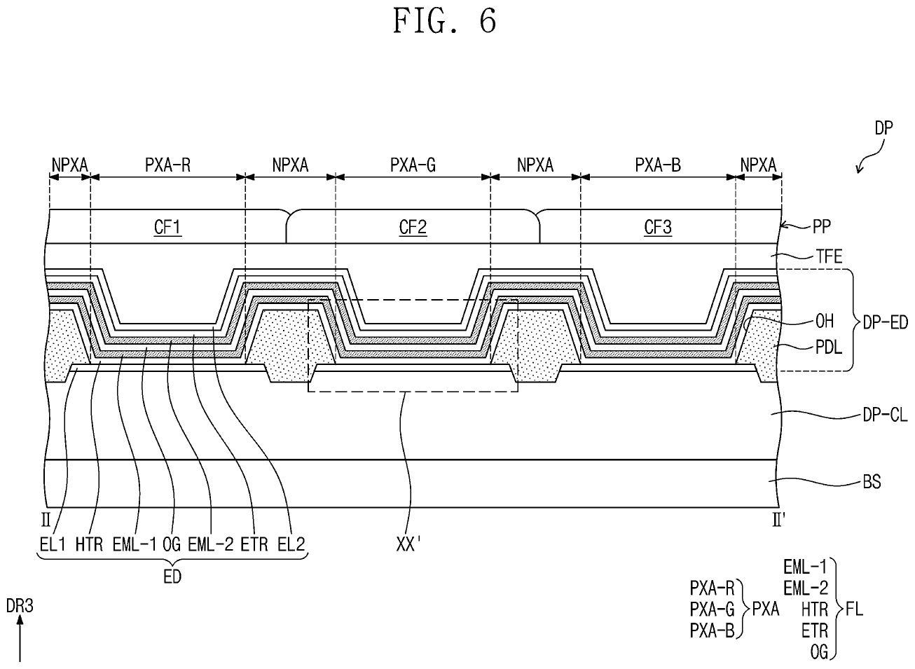

Though not illustrated, an input sensing part may be provided on the display panel DP. The input sensing part may sense an external input applied from the outside. The external input may be a user's input. The user's input may include various types of external inputs such as, for example, parts of the user's body, light, heat, pen and pressure. More particularly, the input sensing part (not illustrated) may be disposed on an encapsulation layer TFE (see FIG. 6) of the display panel DP, which will be explained later. Alternatively, the input sensing part (not illustrated) may be positioned directly on the encapsulation layer TFE (see FIG. 6), or the input sensing part may be disposed directly on an adhesive member (not illustrated) disposed on the encapsulation layer TFE (see FIG. 6). The adhesive member may include common adhesives or sticking agents.

In the disclosure, if an element (or area, layer, part, or the like) is referred to as being “directly disposed” on another element, it means that a third element is not positioned between the element and the other element. That is, if an element is “directly disposed” on another element, it means that the element is in “contact” with the other element.

The housing HAU may accommodate the display panel DP and the like. The housing HAU may be combined with the window member WM.

FIG. 4 is a cross-sectional view of a display panel DP according to an embodiment supported by the present disclosure. FIG. 4 is a cross-sectional view illustrating a part corresponding to line I-I′ in FIG. 3. FIG. 4 is a cross-sectional view schematically illustrating the configuration of the display panel DP. Referring to FIG. 4, the display panel DP may include a base layer BS, a circuit layer DP-CL, a display element layer DP-ED, and an encapsulation layer TFE. In some aspects, the display panel DP may further include an optical layer PP.

The base layer BS may be a member providing a base surface on which the circuit layer DP-CL is disposed. The base layer BS may be a rigid substrate or a flexible substrate capable of bending, folding, rolling, or the like. The base layer BS may be a glass substrate, a metal substrate, or a polymer substrate. However, embodiments of the present disclosure are not limited thereto, and the base layer BS may be an inorganic layer, an organic layer or a composite material layer.

The circuit layer DP-CL may be disposed above the base layer BS. The circuit layer DP-CL may include an insulating layer, a semiconductor pattern, a conductive pattern, and a signal line. After forming an insulating layer, a semiconductor layer, and a conductive layer on the base layer BS by a method including coating, deposition, or the like, the insulating layer, the semiconductor layer, and the conductive layer may be selectively patterned via a plurality of photolithography processes. Then, a semiconductor pattern, a conductive pattern, and a signal line included in the circuit layer DP-CL may be formed.

The display element layer DP-ED may be disposed above the circuit layer DP-CL. The display element layer DP-ED may include a light emitting element (see FIG. 6) which will be explained later. For example, the display element layer DP-ED may include an organic light emitting material, an inorganic light emitting material, an organic-inorganic light emitting material, a quantum dot, a quantum rod, a micro LED, or a nano LED.

The encapsulation layer TFE may be disposed above the display element layer DP-ED. The encapsulation layer TFE may protect the display element layer DP-ED from foreign materials such as, for example, moisture, oxygen, and dust particles. The encapsulation layer TFE may include at least one insulating layer.

The optical layer PP may be disposed on the display panel DP and control reflected light from the display panel DP due to external light. The optical layer PP may include, for example, a polarizing layer or a color filter layer.

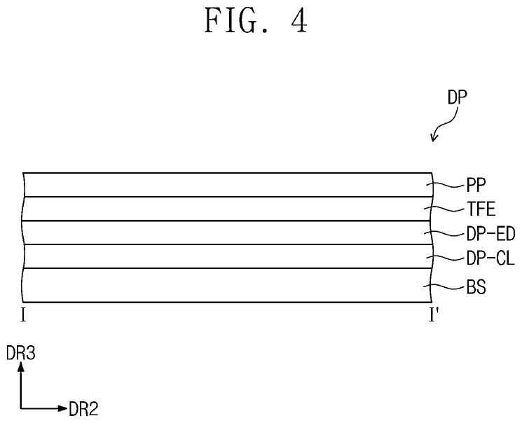

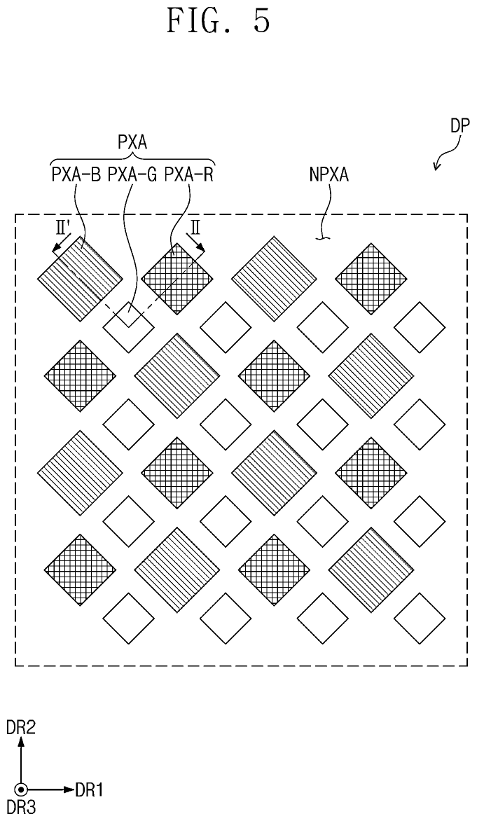

FIG. 5 is a plan view illustrating a display panel DP according to an embodiment. Hereinafter, the same explanation on the display panel DP may be applied to the display panel DP included in the electronic devices EA and EA-a illustrated in FIG. 1 and FIG. 3.

Referring to FIG. 5, the display panel DP may include a light emitting area PXA and a non-light emitting area NPXA. The non-light emitting area NPXA may surround the light emitting area PXA. A plurality of the light emitting areas PXA may be provided. The light emitting area PXA may include a red light emitting area PXA-R, a green light emitting area PXA-G, and a blue light emitting area PXA-B. Each of the red light emitting area PXA-R, the green light emitting area PXA-G, and the blue light emitting area PXA-B may emit light in different wavelength ranges. The red light emitting area PXA-R may emit red light, the green light emitting area PXA-G may emit green light, and the blue light emitting area PXA-B may emit blue light.

The area of the blue light emitting area PXA-B may be the largest, and the area of the green light emitting area PXA-G may be the smallest among the plurality of the light emitting areas PXA-R, PXA-G and PXA-B. However, this is an example, and the areas of the plurality of the light emitting areas PXA-R, PXA-G and PXA-B are not limited thereto. In FIG. 3, the red light emitting areas PXA-R and the blue light emitting areas PXA-B are arranged alternately in one row, and the green light emitting areas PXA-G are separated from the red light emitting areas PXA-R and the blue light emitting areas PXA-B and arranged in another row. However, this is an example, and the arrangement of the plurality of the light emitting areas PXA-R, PXA-G and PXA-B is not limited thereto.

FIG. 6 is a cross-sectional view illustrating a display panel DP according to an embodiment. The base layer BS may include a single-layer or multi-layer structure. For example, the base layer BS may include a first synthetic resin layer, a middle layer of a multi-layer or single-layer structure, and a second synthetic resin layer, stacked in order. The middle layer may be referred to as a base barrier layer. The middle layer may include a silicon oxide (SiOx) layer and an amorphous silicon (a-Si) layer disposed above the silicon oxide layer, without specific limitation. For example, the middle layer may include at least one among a silicon oxide layer, a silicon nitride layer, a silicon oxynitride layer, and an amorphous silicon layer.

Each of the first and second synthetic resin layers may include a polyimide-based resin. In some aspects, each of the first and second synthetic resin layers may include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. In the disclosure, an “α”-based resin means the inclusion of the functional group of “α”.

The circuit layer DP-CL may be disposed on the base layer BS. The circuit layer DP-CL may include a plurality of transistors (not illustrated). Each of the transistors (not illustrated) may include a control electrode, an input electrode, and an output electrode. For example, the circuit layer DP-CL may include a switching transistor and a driving transistor for driving the light emitting element ED of the display element layer DP-ED.

The display element layer DP-ED may include a light emitting element ED and a pixel definition layer PDL. The light emitting element ED may include a first electrode EL1, a second electrode EL2 disposed on the first electrode EL1, and at least one functional layer FL disposed between the first electrode EL1 and the second electrode EL2.

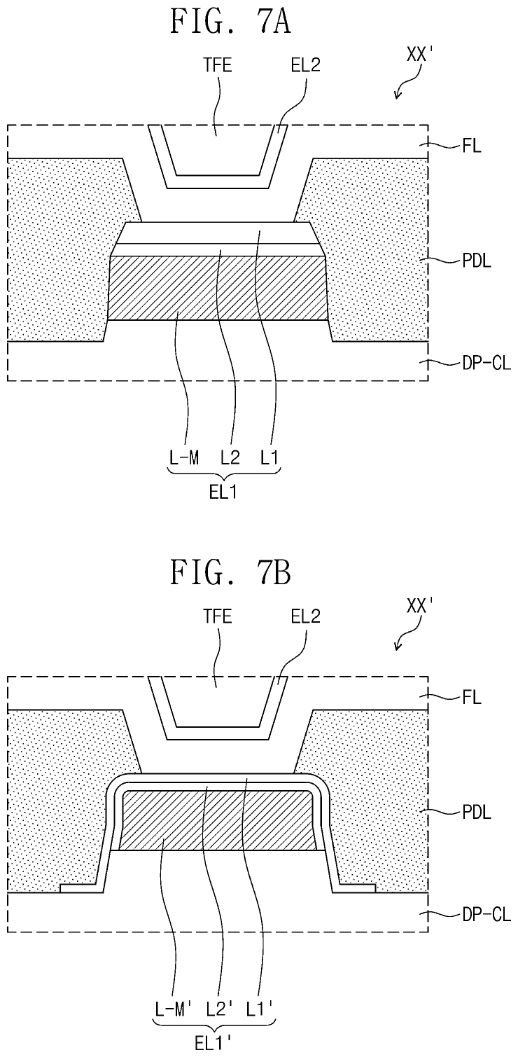

The first electrode EL1 may be an anode. In an embodiment, the first electrode EL1 may include a metal layer L-M (see FIG. 7A), a second layer L2 (see FIG. 7A), and a first layer L1 (see FIG. 7A). Accordingly, the first electrode EL1 may be formed to have a fine structure showing excellent reliability, and the display panel DP including the first electrode EL1 may show excellent display quality. The first electrode EL1 will be explained in more detail later.

The pixel definition layer PDL may have transparent properties or light-absorbing properties. For example, a light-absorbing pixel definition layer PDL may include a black coloring agent. The black coloring agent may include a black dye, or a black pigment. The black coloring agent may include carbon black, a metal such as, for example, chromium, or an oxide thereof. The pixel definition layer PDL may correspond to a shielding pattern having light blocking characteristics.

The pixel definition layer PDL may cover a portion of the first electrode EL1. For example, in the pixel definition layer PDL, a pixel opening OH exposing a portion of the first electrode EL1 may be defined. The pixel definition layer PDL may increase the distance between the edge of the first electrode EL1 and the second electrode EL2. Accordingly, the generation of an arc (e.g., electrical arcing) or the like at the edge of the first electrode EL1 may be prevented by the pixel definition layer PDL.

The second electrode may be a cathode. The second electrode EL2 may be disposed as a common layer. The second electrode EL2 may be referred to as a common electrode. A common voltage may be provided to the second electrode EL2. For example, the second electrode EL2 may include at least one selected among Ag, Mg, Cu, Al, Pt, Pd, Au, Ni, Nd, Ir, Cr, Li, Ca, LiF, Mo, Ti, W, In, Sn, and Zn, a compound of two or more selected therefrom, a mixture of two or more selected therefrom, or an oxide thereof.

At least one functional layer FL may include a first emission layer EML-1 and a second emission layer EML-2 disposed on the first emission layer EML-1. The first emission layer EML-1 and the second emission layer EML-2 may be disposed between the first electrode EL1 and the second electrode EL2. In some aspects, at least one functional layer FL may further include a hole transport region HTR, an electron transport region ETR, and an emission auxiliary part OG.

The light emitting element ED may have a tandem structure including a plurality of emission layers EML-1 and EML-2. The first emission layer EML-1 and the second emission layer EML-2 may be provided as common layers. However, embodiments of the present disclosure are not limited thereto, and the light emitting element ED may include a single emission layer (first emission layer or second emission layer) disposed as a common layer.

Each of the first emission layer EML-1 and the second emission layer EML-2 may include an organic light emitting material and/or an inorganic light emitting material. The first emission layer EML-1 may emit first light, and the second emission layer EML-2 may emit second light that is different from the first light. For example, the first emission layer EML-1 may emit light in a wavelength range of about 450 nm to about 570 nm. The second emission layer EML-2 may emit light in a wavelength range of about 590 nm to about 750 nm. However, this is an example, and the wavelengths of the light emitted from the first emission layer EML-1 and the second emission layer EML-2 are not limited thereto. In another example, the first emission layer EML-1 and the second emission layer EML-2 may emit light in the same wavelength range.

The light emitting element ED including the first emission layer EML-1 and the second emission layer EML-2 may emit white light. However, embodiments of the present disclosure are not limited thereto, and the light emitting element ED including the first emission layer EML-1 and the second emission layer EML-2 may emit blue light.

The hole transport region HTR may be disposed between the first electrode EL1 and the first emission layer EML-1. The hole transport region HTR may include at least one among a hole injection layer, a hole transport layer, and an electron blocking layer. The hole transport region HTR may include known hole injection materials and/or hole transport materials. The hole transport region HTR may be disposed as a common layer. However, embodiments of the present disclosure are not limited thereto, and the hole transport region HTR may be patterned and provided in the pixel opening OH.

The electron transport region ETR may be disposed between the second emission layer EML-2 and the second electrode EL2. The electron transport region ETR may include at least one of an electron injection layer, an electron transport layer, or a hole blocking layer. The electron transport region ETR may include known electron injection materials and/or electron transport materials. The electron transport region ETR may be disposed as a common layer. However, embodiments of the present disclosure are not limited thereto, and the electron transport region ETR may be patterned and provided in the pixel opening OH.

An emission auxiliary part OG may be disposed between the first emission layer EML-1 and the second emission layer EML-2. The emission auxiliary part OG may include a single layer or multiple layers. The emission auxiliary part OG may include a charge generating layer. In some aspects, the emission auxiliary part OG may further include a hole transport region disposed on the charge generating layer and an electron transport region disposed below the charge generating layer. The emission auxiliary part OG may be provided as a common layer. However, embodiments of the present disclosure are not limited thereto, and the emission auxiliary part OG may be patterned and provided in the pixel opening OH.

The encapsulation layer TFE may cover the light emitting element ED. The encapsulation layer TFE may seal the display element layer DP-ED. The encapsulation layer TFE may be disposed on the second electrode EL2 and may be disposed while filling the pixel opening OH.

The encapsulation layer TFE may be a thin film encapsulation layer. The encapsulation layer TFE may be one layer or a stacked layer of multiple layers. The encapsulation layer TFE may include at least one insulating layer. The encapsulation layer TFE according to an embodiment may include at least one inorganic layer (hereinafter, encapsulating inorganic layer). In some aspects, the encapsulation layer TFE according to an embodiment may include at least one organic layer (hereinafter, encapsulating organic layer) and at least one encapsulating inorganic layer.

The encapsulating inorganic layer may protect the display element layer DP-ED from humidity/oxygen, and the encapsulating organic layer may protect the display element layer DP-ED from foreign materials such as, for example, dust particles. The encapsulating inorganic layer may include silicon nitride, silicon oxynitride, silicon oxide, titanium oxide, or aluminum oxide, without specific limitation. The encapsulating organic layer may include an acrylic compound, an epoxy-based compound and the like. The encapsulating organic layer may include a photopolymerizable organic material, without specific limitation.

The display panel DP may include a light emitting area PXA and a non-light emitting area NPXA. The light emitting area PXA may be an area emitting light produced in the light emitting element ED. The light emitting area PXA may be an area divided by the pixel definition layer PDL. The non-light emitting area NPXA may be an area between adjacent light emitting areas PXA and may be an area corresponding to the pixel definition layer PDL. The light emitting area PXA may correspond to a pixel.

The light emitting area PXA may include a red light emitting area PXA-R, a green light emitting area PXA-G, and a blue light emitting area PXA-B. The red light emitting area PXA-R, the green light emitting area PXA-G, and the blue light emitting area PXA-B may be spaced apart from each other on a plane.

In FIG. 6, as an illustration, the optical layer PP is illustrated as including first to third filters CF1, CF2 and CF3. The first filter CF1 may be disposed to correspond to the red light emitting area PXA-R, the second filter CF2 may be disposed to correspond to the green light emitting area PXA-G, and the third CF3 may be disposed to correspond to the blue light emitting area PXA-B.

For example, the first filter CF1 may be a red filter, the second filter CF2 may be a green filter, and the third filter CF3 may be a blue filter. Each of the filters CF1, CF2 and CF3 may include a polymer photosensitive resin and a pigment or dye. The first filter CF1 may include a red pigment or dye, the second filter CF2 may include a green pigment or dye, and the third filter CF3 may include a blue pigment or dye. However, embodiments of the present disclosure are not limited thereto, and in some examples, the third filter CF3 may not include a pigment or dye. For example, the third filter CF3 may include a polymer photosensitive resin but not include a pigment or dye. The third filter CF3 may be optically transparent. The third filter CF3 may be formed from a transparent photosensitive resin.

A portion of each of the first to third filters CF1, CF2 and CF3 may be disposed in the non-light emitting area NPXA. However, embodiments of the present disclosure are not limited thereto, and the first to third filters CF1, CF2 and CF3 may not be disposed in the non-light emitting area NPXA.

Between two adjacent filters among the first to third filters CF1, CF2 and CF3, a light blocking part (not illustrated) may be disposed. The light blocking part may be black matrix. The light blocking part may be formed by including an organic light blocking material or an inorganic light blocking material including a black pigment or a black dye. The light blocking part may prevent light leakage phenomenon and may divide the boundaries between adjacent filters CF1, CF2 and CF3.

FIG. 7A and FIG. 7B are enlarged cross-sectional views on a portion of the display panel according to an embodiment supported by the present disclosure. In each of FIG. 7A and FIG. 7B, a region XX′ of FIG. 6 is enlarged and illustrated. In FIG. 7A and FIG. 7B, the configurations of the first electrodes EL1 and EL1′ of embodiments are particularly illustrated. In some embodiments, in the disclosure, the “first electrode” may be referred to as an “electrode.”

Referring to FIG. 7A, the first electrode EL1 may include a plurality of conductive layers. The first electrode EL1 may include at least a first layer L1. The first electrode EL1 may include, for example, a metal layer L-M, a second layer L2 disposed on the metal layer L-M, and a first layer L1 disposed on the second layer L2.

The total thickness of the first electrode EL1 including the first layer L1, the second layer L2 and the metal layer L-M may range from about 50 nm to about 150 nm. If the thickness is greater than about 150 nm, the patterning of the first electrode EL1 into a fine structure is not easy, ultra-high resolution may not be realized, and the first electrode EL1 with a thickness of less than about 50 nm may be difficult to realize. In an embodiment, the first electrode EL1 with a thickness ranging from about 50 nm to about 150 nm may be patterned into a fine structure via dry etching. Accordingly, the display panel DP including the first electrode EL1 may realize ultra-high resolution.

The head-mounted display device (electronic device, EA) illustrated in FIG. 1 may be capable of ultra-high resolution to realize virtual reality and augmented reality, and the display panel DP including the first electrode EL1 may realize an ultra-high resolution of about 3000 ppi or more. The electronic device EA including the display panel DP of an embodiment may show excellent display quality.

The first layer L1 includes a transparent conductive oxide (TCO). The first layer L1 includes a transparent conductive oxide containing indium. The first layer L1 may include, for example, indium tin oxide (ITO). Alternatively, the first layer L1 may include indium zinc oxide (IZO), or indium zinc tin oxide (ITZO). The first layer L1 may be a single layer composed of the transparent conductive oxide containing indium. That is, the first layer L1 may not include another material other than the transparent conductive oxide containing indium, and may have a single layer structure that does not contain multiple layers or sections in which an identifiable interface is defined.

The thickness of the first layer L1 may range from about 2 nm to about 12 nm. For example, the thickness of the first layer L1 may be about 5 nm. Achieving a uniform thickness for a first layer with a thickness of less than about 2 nm is difficult, and a first layer formed with a thickness of greater than about 12 nm may have reduced stability due to self-stress. In an embodiment, the first layer L1 which has a thickness ranging from about 2 nm to about 12 nm may be formed into a uniform thickness and may exhibit excellent processability.

The first electrode EL1 may further include the metal layer L-M disposed below the first layer L1. The metal layer L-M may include a conductive metal. The metal layer L-M may include, for example, aluminum. The metal layer L-M may include an aluminum alloy. The metal layer L-M may include an aluminum alloy composed of alloy atoms and alloy atoms. In the disclosure, the alloy atoms means atoms excluding the aluminum atoms among the atoms constituting the aluminum alloy. The alloy atom may be one or multiple. The aluminum alloy constituting the metal layer L-M may include at least one of titanium (Ti), nickel (Ni) or lanthanum (La) as the alloy atom. For example, the metal layer L-M may include an alloy composed of aluminum and titanium. Otherwise, the metal layer L-M may include an alloy composed of aluminum, nickel, and lanthanum.

The metal layer L-M may have a ratio of the alloy atoms excluding the aluminum atoms of about 0.01 at % (atomic percent) to about 0.1 at % on the basis of 100 at % of the atomic ratio of the aluminum alloy. The generation of a hillock of the metal layer L-M may be prevented if the ratio of the alloy atoms excluding the aluminum atoms is about 0.01 at % or more. The hillock may be protrusions on the surface of the configuration. The metal layer L-M having the ratio of the alloy atoms excluding the aluminum atoms of about 0.1 at % or less may maintain resistance and show excellent light reflectance. The metal layer L-M may be a configuration reflecting light directed downward among the light generated from the above-described first and second emission layers EML-1 and EML-2 (see FIG. 6) toward upward. Accordingly, the higher the light reflectance of the metal layer L-M, the better the display quality.

If the ratio of the alloy atoms is less than about 0.01 at %, heat resistance of the aluminum alloy is reduced, and a hillock may occur in a high temperature process. The manufacturing process of the display panel DP may include a step of forming a pixel definition layer PDL after the step of forming the first electrode EL1, and the step of forming the pixel definition layer PDL may be performed at a high temperature of about 250° C. or higher. If the ratio of the alloy atoms is less than about 0.01 at %, the aluminum alloy is not suitable as the metal layer L-M of the first electrode EL1, because a hillock occurs in a high temperature process of about 250° C. or higher. If the ratio of the alloy atoms is greater than about 0.1 at %, the resistance of the metal layer L-M may increase, and the light reflectance of the metal layer L-M may decrease. If the light reflectance of the metal layer L-M decreases, light directed upward decreases, thereby deteriorating display quality.

The thickness of the metal layer L-M may range from about 60 nm to about 120 nm. For example, the thickness of the metal layer L-M may be about 100 nm. The first layer with a thickness greater than about 120 nm results in the increase of the size of aluminum particles and an increase in surface roughness. If the surface roughness increases, diffuse reflection occurs, and diffuse reflection causes the deterioration of display quality. In some aspects, the first layer with a thickness of greater than about 120 nm is not easy to form by dry etching and may not be patterned into a fine structure.

The metal layer L-M with a thickness of less than about 60 nm may transmit light, and the light directed upward may be reduced, thereby deteriorating display quality. In an embodiment, the metal layer L-M with a thickness of about 60 nm to about 120 nm exhibits low transmittance and excellent light reflectance, thereby improving display quality.

The first electrode EL1 may include a second layer L2 disposed between the first layer L1 and the metal layer L-M. The second layer L2 may be a metal oxide layer which is formed by the oxidation of a portion of a metal included in the metal layer L-M. The second layer L2 may include, for example, aluminum oxide. The second layer L2 may be disposed directly between the first layer L1 and the metal layer L-M. The second layer L2 may be disposed directly on the metal layer L-M, and the first layer L1 may be disposed directly on the second layer L2. In some embodiments, in the disclosure, if one element is disposed directly between other elements, it means that no third element is disposed between one element and the other elements. In other words, if one element is disposed directly between other elements, it means that one element is in contact with the other elements.

The second layer L2 may be a layer formed by the oxidation of a portion of a metal included in the metal layer L-M according to the contact between the metal layer L-M and a preliminary layer for forming the first layer L1 during a forming process of the metal layer L-M and the first layer L1. Since the preliminary layer for forming the first layer L1 is formed from indium tin oxide or the like, the second layer L2 may be an aluminum oxide layer formed by the oxidation of a portion of aluminum included in the metal layer L-M. The thickness of the second layer L2 may range, for example, from about 1 nm to about 5 nm. If the thickness of the second layer L2 is greater than about 5 nm, light absorption ratio may be high, the driving voltage of the first electrode EL1 may increase, and the deterioration of display quality may be induced.

In FIG. 7B, the shape of a first electrode EL1′ of an embodiment that is different from the first electrode EL1 of an embodiment illustrated in FIG. 7A.

Referring to FIG. 7B, the first electrode EL1′ may include a plurality of conductive layers. The first electrode EL1′ includes at least a first layer L1′. The first electrode EL1′ may include, for example, a metal layer L-M′, a second layer L2′ disposed on the metal layer L-M′, and a first layer L1′ disposed on the second layer L2′.

The shapes of the first electrode EL1 illustrated in FIG. 7A and the first electrode EL1′ illustrated in FIG. 7B may change depending on process sequence for forming the metal layers L-M and L-M′, the second layer L2 and L2′, and the first layer L1 and L1′.

In an embodiment, the first electrode EL1 illustrated in FIG. 7A may be formed by forming a preliminary layer structure for forming the metal layer L-M and the first layer L1, and then patterning preliminary layers for forming the metal layer L-M and the first layer L1 together. That is, the metal layer L-M and the first layer L1 may be formed at the same time via etching. The second layer L2 may be an oxide layer formed by the oxidation of a portion of a metal element included in the preliminary layer for forming the metal layer L-M during forming the preliminary layer for forming the first layer L1. In the first electrode EL1 of an embodiment, the first layer L1 may entirely overlap with the metal layer L-M, and the first layer L1 may non-overlap with the remaining area excluding the area where the metal layer L-M is disposed.

In another embodiment, the first electrode EL1′ illustrated in FIG. 7B may be formed by forming and patterning a preliminary layer for forming the metal layer L-M′, and forming and patterning a preliminary layer for forming the first layer L1′ on the patterned metal layer L-M′. That is, the metal layer L-M′ and the first layer L1′ may be formed by etching through separate etching steps. The second layer L2′ may be an oxide layer formed by the oxidation of a portion of a metal element included in the metal layer L-M′ during forming the preliminary layer for forming the first layer L1′. In the first electrode EL1′ of an embodiment, the first layer L1′ may partially overlap with the metal layer L-M′, and the remaining partial first layer L1′ may non-overlap with the metal layer L-M′. The remaining portion of the first layer L1′ non-overlap with the metal layer L-M′ may be disposed on the circuit layer DP-CL.

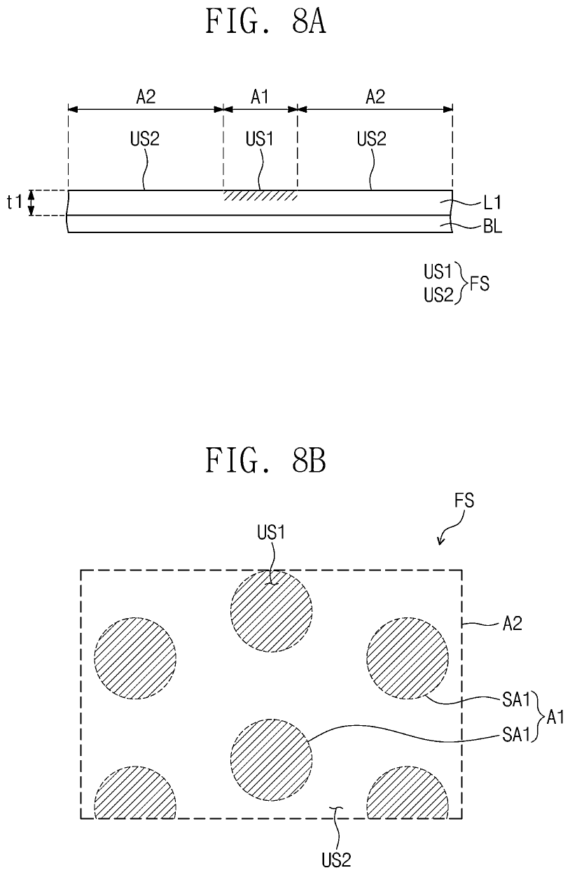

FIG. 8A is a cross-sectional view of some elements of the first electrode according to an embodiment supported by the present disclosure. FIG. 8B is a plan view of some elements of the first electrode according to an embodiment supported by the present disclosure. In FIG. 8A and FIG. 8B, the shape according to a cross-sectional view and the shape according to a plan view of a portion of the first layer L1 included in the first electrode according to an embodiment supported by the present disclosure are schematically illustrated.

Referring to FIG. 7A and FIG. 8A together, the first layer L1 included in the first electrode EL1 of an embodiment includes a first area A1 and a second area A2 adjacent to the first area A1.

The surface FS of the first layer L1 includes a first surface US1 corresponding to the first area A1, and a second surface US2 corresponding to the second area A2. In some embodiments, the surface FS of the first layer L1 may be a portion of the top or the side surface of the first layer L1 illustrated in FIG. 7A. In some examples, the surface FS of the first layer L1 may be a portion of the top or the side surface of the first layer L1′ illustrated in FIG. 7B. The base layer BL on which the first layer L1 providing the surface FS is disposed may be an element providing a base surface on which the first layer L1 is disposed. For example, the base layer BL may be the metal layer L-M or the second layer L2 illustrated in FIG. 7A. The base layer BL may be the insulating layer included in the circuit layer DP-CL illustrated in FIG. 7B.

The first surface US1 and the second surface US2 may have an integrated shape but may be slightly different in terms of respective component content and physical properties. In an embodiment, the indium content of the first surface US1 may be greater than the indium content of the second surface US2. In an embodiment, the surface roughness of the first surface US1 may be greater than the surface roughness of the second surface US2.

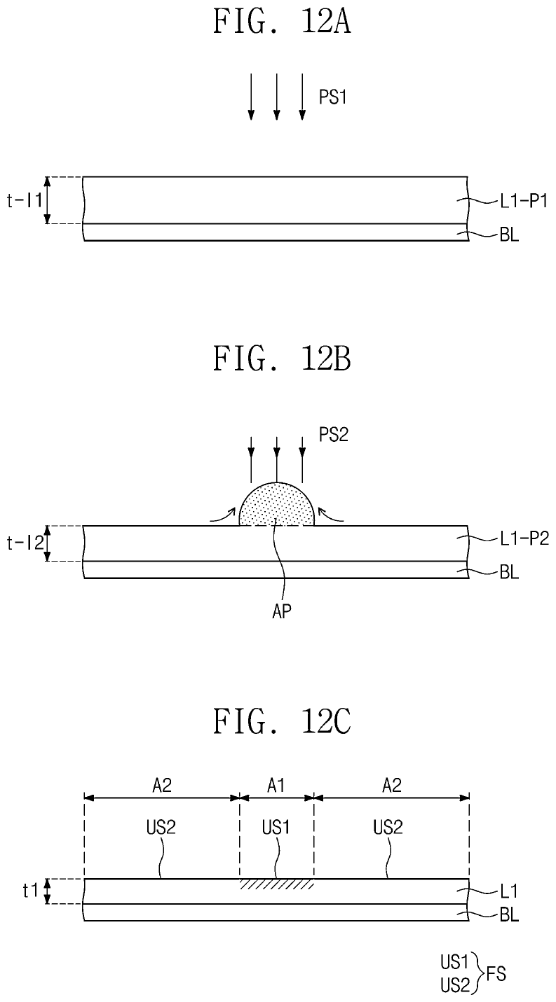

The first area A1 may correspond to an area etched after forming an agglomeration pattern AP (see FIG. 12B) in the step of etching a preliminary layer for forming the first layer L1. The first surface US1 corresponding to the first area A1 may correspond to a surface etched after forming the agglomeration pattern AP (see FIG. 12B), and may be a surface having higher surface roughness and higher indium content compared to the second surface US2 corresponding to the second area A2.

Referring to FIG. 7A and FIG. 7B together, the second area A2 may surround at least a portion of the first area A1. The first area A1 may be provided in plurality, and the second area A2 may surround at least a portion of each of the plurality of the first area A1. The first area A1 may include a plurality of first sub-areas SA1 that are spaced apart from each other. The second area A2 may surround each of the plurality of first sub-areas SA1. In some embodiments, in FIG. 7B, each of the plurality of the first sub-areas SA1 included in the first area A1 is an illustration illustrated to have a circular shape with the same size on a plane, but is not limited thereto, and each of the plurality of the first sub-areas SA1 included in the first area A1 may have various shapes on a plane. In an embodiment, each of the plurality of the first sub-areas SA1 may have a different size and various randomly formed shapes. The shape of each of the plurality of the first sub-areas SA1 may correspond to the shape of the agglomeration pattern AP (see FIG. 12B) formed in the step of etching the preliminary layer for forming the first layer L1.

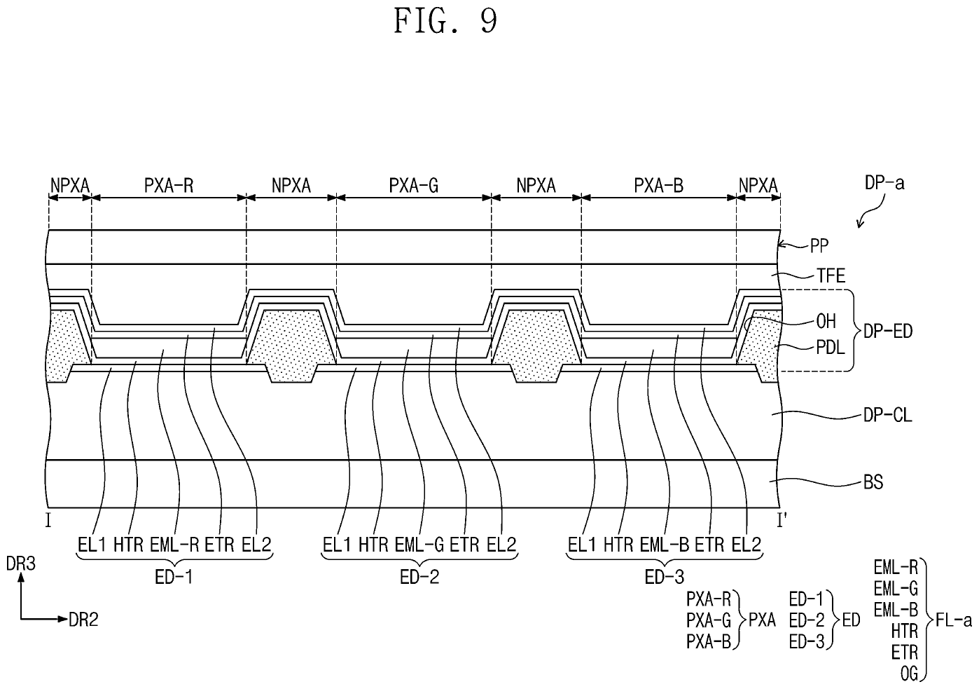

FIG. 9 is a cross-sectional view illustrating another embodiment supported by the present disclosure and is a cross-sectional view illustrating a display panel DP-a. Hereinafter, in the description of FIG. 9, repeated descriptions of content that overlaps with the content described with reference to FIG. 1 to FIG. 8B are omitted for brevity, and the differences will be mainly explained.

Compared to the display panel DP illustrated in FIG. 6, the display panel DP-a illustrated in FIG. 9 is different in that a light emitting element ED includes a first to third light emitting elements ED-1, ED-2 and ED-3. In FIG. 9, an optical layer PP may include the first to third filters CF1, CF2 and CF3 illustrated in FIG. 5 or the polarizing layer.

The first to third light emitting elements ED-1, ED-2 and ED-3 may be spaced apart in a second direction DR2 that is perpendicular to a thickness direction DR3. Each of the first to third light emitting elements ED-1, ED-2 and ED-3 may include a first electrode EL1, a second electrode EL2 disposed on the first electrode EL1, and a functional layer FL-a disposed between the first electrode EL1 and the second electrode EL2. Compared to the functional layer FL illustrated in FIG. 5, the functional layer FL-a in FIG. 9 is different in including a red emission layer EML-R, a green emission layer EML-G and a blue emission layer EML-B, which are patterned and provided in a pixel opening OH.

The first light emitting element ED-1 may include the red emission layer EML-R and emit red light. The first light emitting element ED-1 may be disposed corresponding to a red light emitting area PXA-R. The second light emitting element ED-2 may include the green emission layer EML-G and emit green light. The second light emitting element ED-2 may be disposed corresponding to a green light emitting area PXA-G. The third light emitting element ED-3 may include the blue emission layer EML-B and emit blue light. The third light emitting element ED-3 may be disposed corresponding to a blue light emitting area PXA-B.

In FIG. 9, each of the first to third light emitting elements ED-1, ED-2 and ED-3 includes one emission layer, but embodiments of the present disclosure are not limited thereto. For example, each of the first to third light emitting elements ED-1, ED-2 and ED-3 may include a plurality of emission layers emitting light in the same wavelength range.

The first electrode EL1 included in the display panel of an embodiment may be manufactured by a method of manufacturing an electrode of an embodiment, which will be explained hereinafter.

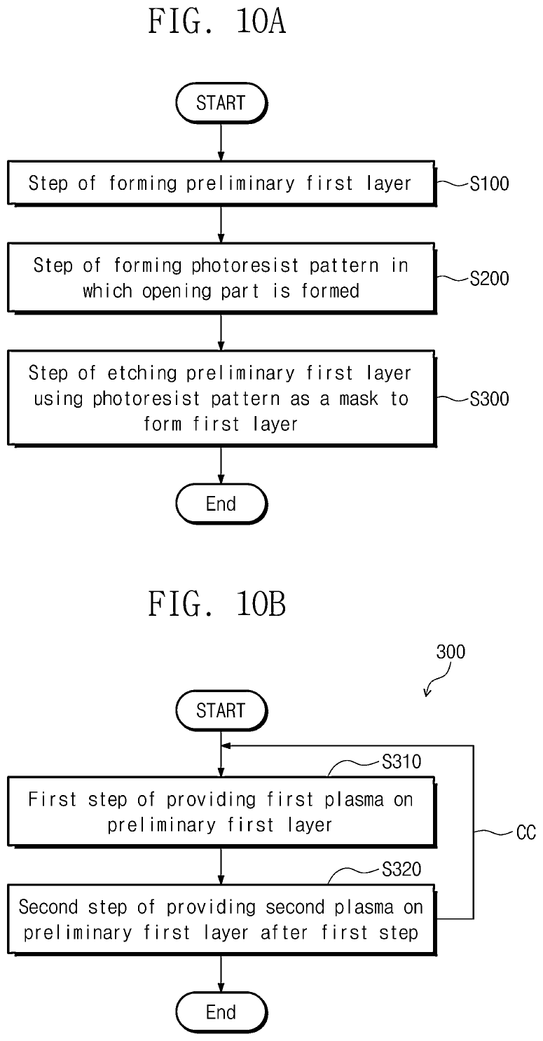

FIG. 10A is a flowchart illustrating a method of manufacturing an electrode according to an embodiment supported by the present disclosure. FIG. 10B is a flowchart illustrating some steps in the method of manufacturing an electrode according to an embodiment supported by the present disclosure. FIG. 10B illustrates each step included in the step of etching a preliminary first layer in association with forming a first layer (S300) in the method of manufacturing an electrode according to an embodiment supported by the present disclosure.

In the descriptions of the method and processes herein, the operations may be performed in a different order than the order shown and/or described, or the operations may be performed in different orders or at different times. Certain operations may also be left out of the method and processes, one or more operations may be repeated, or other operations may be added. Descriptions that an element “may be disposed,” “may be formed,” “may be etched,” and the like include methods, processes, and techniques for disposing, forming, positioning, and modifying the element, and the like in accordance with example aspects described herein.

Referring to FIG. 10A, the method of manufacturing an electrode according to an embodiment supported by the present disclosure includes a step of forming a preliminary first layer (S100), a step of forming a photoresist pattern on the preliminary first layer, in which an opening part is formed (S200), and a step of etching the preliminary first layer using the photoresist pattern as a mask in association with forming a first layer (S300). Accordingly, for example, the photoresist pattern formed at S200 may include an opening part, and at S300, the method may include forming the first layer by etching the preliminary first layer using the photoresist pattern as a mask.

Referring to FIG. 10B, the step of etching the preliminary first layer in association with forming the first layer (S300) includes a first step of providing first plasma onto the preliminary first layer (S310), and a second step of providing second plasma onto the preliminary first layer after the first step (S320).

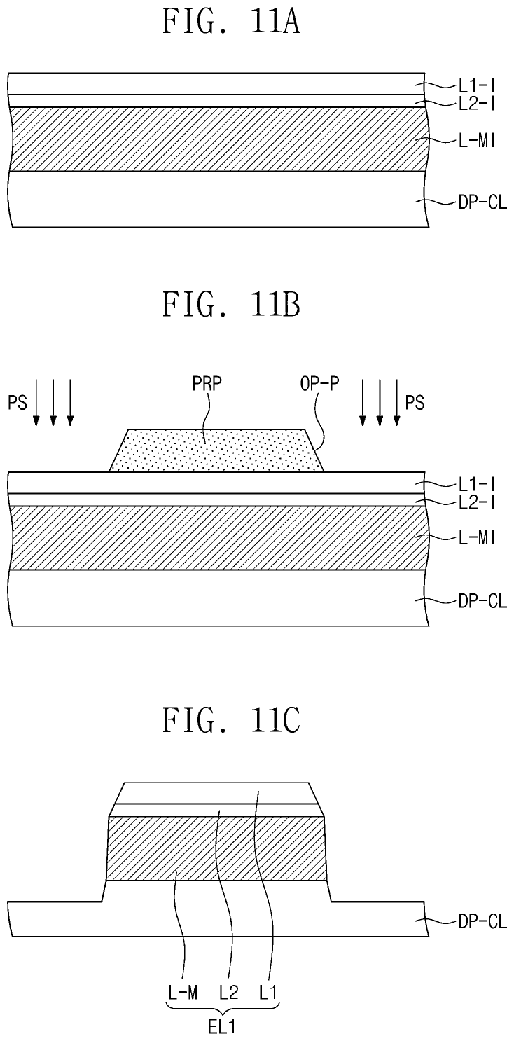

FIG. 11A to FIG. 11C are cross-sectional views sequentially illustrating the method of manufacturing an electrode according to an embodiment supported by the present disclosure. FIG. 12A to FIG. 12C are cross-sectional views illustrating some steps in the method of manufacturing an electrode according to an embodiment supported by the present disclosure. In FIG. 12A to FIG. 12C, steps included in the step of etching the preliminary first layer in association with forming the first layer in the method of manufacturing an electrode according to an embodiment supported by the present disclosure, are illustrated.

Referring to FIG. 10A, FIG. 11A and FIG. 11B, the method of manufacturing an electrode according to an embodiment supported by the present disclosure includes a step of forming a preliminary first layer L1-l (S100) and a step of forming a photoresist pattern PRP in which an opening part OP-P is formed, on the preliminary first layer L1-l (S200). For example, the photoresist pattern PRP formed may include the opening part OP-P.

In an example, the preliminary first layer L1-l is formed from a transparent conductive oxide. In some examples, the preliminary first layer L1-l may be formed from a transparent conductive oxide containing indium. The preliminary first layer L1-l may be formed from, for example, indium tin oxide (ITO). In an alternative example, the preliminary first layer L1-l may include indium zinc oxide (IZO) or indium zinc tin oxide (IZTO). The preliminary first layer L1-l may be a single layer composed of a transparent conductive oxide containing indium. That is, the preliminary first layer L1-l may not include a material other than the transparent conductive oxide containing indium, and may have a single layer structure that does not contain multiple layers or sections in which an identifiable interface is defined.

The method may include forming the preliminary first layer L1-l on a preliminary metal layer L-Ml. The method may include forming the preliminary metal layer L-Ml from a conductive metal. The preliminary metal layer L-Ml may be formed from, for example, aluminum. The preliminary metal layer L-Ml may be formed from an aluminum alloy. The preliminary metal layer L-Ml may be formed from an aluminum alloy composed of aluminum atoms and alloy atoms. In some examples, the aluminum alloy may include one or more alloy atoms. The method may include forming the aluminum alloy constituting the preliminary metal layer L-Ml using at least one among titanium (Ti), nickel (Ni) and lanthanum (La) as the alloy atom. For example, the method may include forming the preliminary metal layer L-Ml of an alloy composed of aluminum and titanium. Otherwise, the method may include forming the preliminary metal layer L-Ml from an alloy composed of aluminum, nickel, and lanthanum.

In the process of forming the preliminary first layer L1-l on the preliminary metal layer L-Ml, the method may include forming a preliminary second layer L2-l between the preliminary first layer L1-l and the preliminary metal layer L-Ml. The preliminary second layer L2-l may be a layer formed by the oxidation of a portion of a metal contained in the preliminary metal layer L-Ml through the contact of the preliminary metal layer L-Ml with the preliminary first layer L1-l. According to the formation of the preliminary first layer L1-l from indium tin oxide or the like, the preliminary second layer L2-l may be an aluminum oxide layer formed by the oxidation of a portion of aluminum contained in the preliminary metal layer L-Ml.

The method may include forming the photoresist pattern PRP on the preliminary first layer L1-l. The photoresist pattern PRP may be a pattern formed by the exposure of a portion of a photosensitive layer through a mask. The method may include using the photoresist pattern PRP as a mask pattern for etching the preliminary first layer L1-l. The method may include forming the photoresist pattern PRP using a positive photosensitive solution or a negative photosensitive solution.

Referring to FIG. 11B and FIG. 11C together, the method may include dry etching the preliminary first layer L1-l. The method may include dry etching the preliminary first layer L1-l by plasma PS using the photoresist pattern PRP as a mask. In an example, the method may include using first plasma (e.g., hydrogen (H₂) plasma) and second plasma (e.g., for example, argon (Ar) plasma) in association with dry etching the preliminary first layer L1-l. A process for dry etching the preliminary first layer L1-l will be explained in more detail in the explanation with respect to FIG. 12A to FIG. 12C later herein. The method may include forming a first layer L1 through the dry etching of the preliminary first layer L1-l.

In the step of dry etching the preliminary first layer L1-l, the preliminary metal layer L-Ml may also be etched in association with forming a metal layer L-M. That is, the method may include forming the metal layer L-M and the first layer L1 together through one etching process. In the process of etching the preliminary first layer L1-l and the preliminary metal layer L-Ml together, the method may further include etching the preliminary second layer L2-l in association with forming a second layer L2. For example, the method may include etching the preliminary first layer L1-l, the preliminary metal layer L-Ml, and the preliminary second layer L2-l in the same etching process.

Referring to FIG. 10B, FIG. 12A and FIG. 12B together, the step of forming a first layer (S300) includes a first step of providing first plasma to a preliminary first layer L1-P1 (S310) and a second step of providing second plasma on the preliminary first layer L1-P2 (S320). The first plasma includes hydrogen (H₂) plasma.

After the first step of providing first plasma to the preliminary first layer L1-P1 (S310), indium in the transparent conductive oxide included in the preliminary first layer L1-P1 agglomerates and forms an agglomeration pattern AP. In the first step (S310) for providing the first plasma, the transparent conductive oxide included in the preliminary first layer L1-P1 includes an indium element, and indium oxide in the transparent conductive oxide included in the preliminary first layer L1-P1 may be metalized by hydrogen (H₂). Then, the shape of at least a portion of the metalized indium element may be modified due to surface tension or the like, and an agglomeration pattern AP in which indium element is agglomerated may be formed. The agglomeration pattern AP may have a shape that protrudes from the top of the preliminary first layer L1-P2. In some embodiments, in FIG. 12B, the agglomeration pattern AP is illustrated as having a semicircular shape in a cross-sectional view, but the agglomeration pattern AP is not limited thereto. For example, the agglomeration pattern AP may protrude from the top of the preliminary first layer L1-P2 and be of various shapes supportive of aspects of the present disclosure.

In an example, the method may include performing the first step for providing the first plasma to the preliminary first layer L1-P1 (S310) for about 30 seconds or more. The method may include performing the first step (S310), for example, for a duration ranging from about 30 seconds to about 200 seconds. If the first step (S310) is performed for less than about 30 seconds, the time for providing the hydrogen plasma is not sufficient, and the size of the agglomeration pattern AP may be insufficient, and which may reduce etching efficiency. If the first step (S310) is performed for more than about 200 seconds, the process time may be increased excessively, which may decrease process efficiency.

In the first step (S310), the hydrogen (H₂) plasma included in the first plasma may have an ion fluence ranging from about 0.5×10¹⁷ cm⁻² to less than about 1.5×10¹⁷ cm⁻². The ion fluence of the hydrogen (H₂) plasma may be, for example, about 1.0×10¹⁷ cm⁻². In some aspects, adjusting the ion fluence of the hydrogen (H₂) plasma according to the above range may prevent damage to the preliminary first layer L1-P1 (e.g., may prevent a decrease in the film quality of the preliminary first layer L1-P1) and secure high etching selectivity.

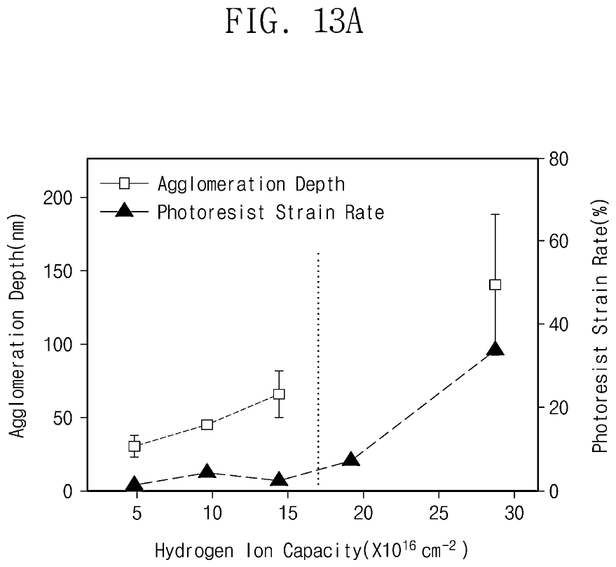

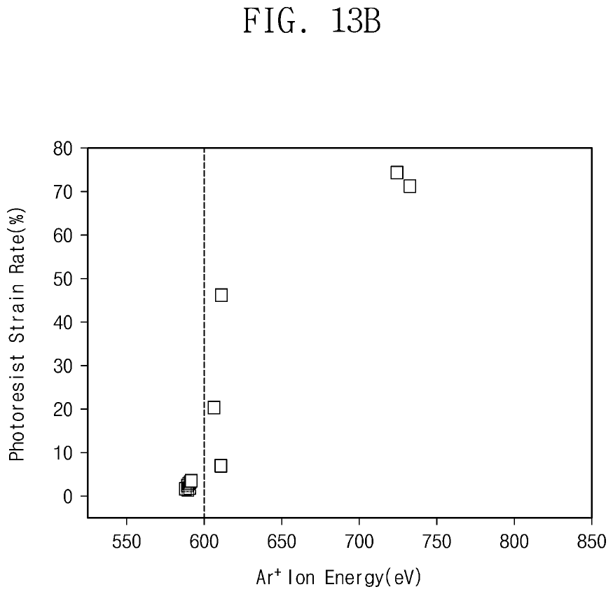

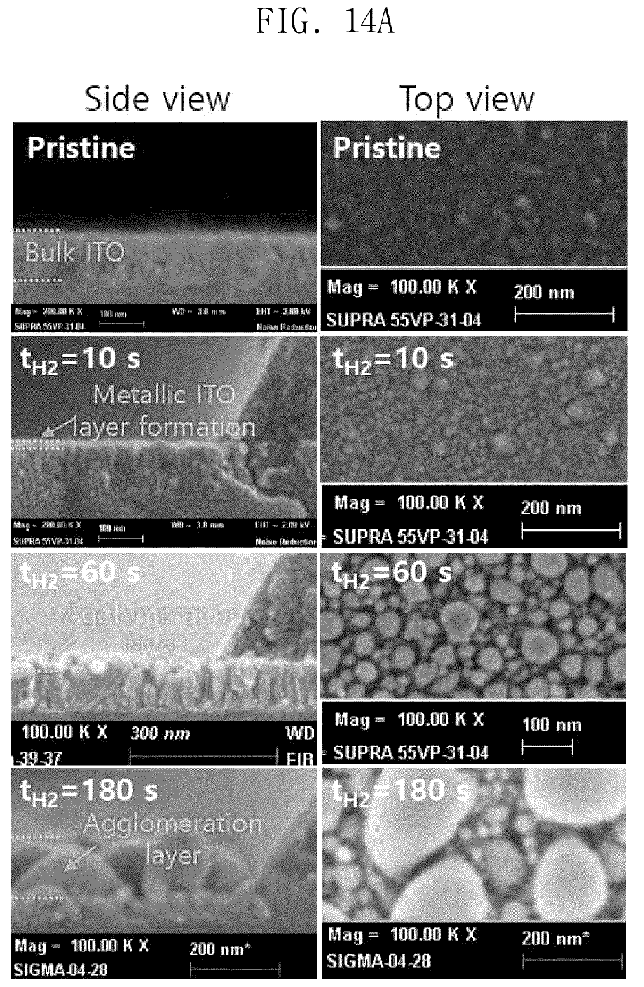

FIG. 13A is a graph illustrating the agglomeration depth and the strain rate of a photoresist pattern in accordance with the hydrogen ion capacity of the hydrogen plasma in the first step described with reference to S310. Referring to FIG. 13A, it can be confirmed that at a point where the hydrogen ion capacity is less than about 1.5×10¹⁷ cm⁻², the strain rate of the photoresist pattern is small and less than about 10%, and the forming depth of the agglomeration pattern is controlled to less than about 100 nm, but if the hydrogen ion capacity increases to about 1.5×10¹⁷ cm⁻² or more, the strain rate of the photoresist pattern increases. Particularly, at a point where the hydrogen ion capacity is about 2.9×10¹⁷ cm⁻², the forming depth of the agglomeration pattern is excessively large to a degree of about 100 nm to about 200 nm, and the strain rate of the photoresist pattern increases to about 30% or more, and thus, it can be expected that defects such as, for example, damage to the film quality of the preliminary first layer L1-P1 may occur.

Referring to FIG. 10B, FIG. 12A and FIG. 12B, the agglomeration of an indium element and the formation of the agglomeration pattern AP following the first step (S310) may result in a thickness t-I2 of the preliminary first layer L1-P2. The thickness t-I2 of the preliminary first layer L1-P2 may be less than a thickness t-I1 of the preliminary first layer L1-P1 prior to the first step (S310).

In FIG. 12B, the formation of one agglomeration pattern AP is illustrated as an example, but a plurality of agglomeration patterns AP may be formed in the first step for providing the first plasma (S310).

Referring to FIG. 11B, FIG. 12B and FIG. 12C together, after forming the agglomeration pattern AP, the method may include providing second plasma onto the preliminary first layer L1-P2 to etch the agglomeration pattern AP. The agglomeration pattern AP may be physically etched by the second plasma. The second plasma may include a reaction gas having low reactivity with the transparent conductive oxide containing indium, included in the preliminary first layer L1-P2. The second plasma may include an inert gas, such as, for example, a nitrogen (N₂) gas. The second plasma may include, for example, argon (Ar) plasma. Regarding the argon gas included in the second plasma, the method may include providing the argon gas in an ion state and physically etching the agglomeration pattern AP through a sputtering process.

The method may include etching and removing at least a portion of the agglomeration pattern AP by the argon (Ar) plasma included in the second plasma. Removing the agglomeration pattern AP by the second plasma may provide a first layer L1 having a surface FS that is a planar surface. As described herein, the first layer L1 includes a first area A1 and a second area A2 adjacent to the first area A1, and the surface FS of the first layer L1 includes a first surface US1 corresponding to the first area A1 and a second surface US2 corresponding to the second area A2. The first surface US1 and the second surface US2 have an integrated shape but may be slightly different in terms of respective component content and physical properties of the first surface US1 and the second surface US2. In an embodiment, the indium content of the first surface US1 may be greater than the indium content of the second surface US2. In an embodiment, the surface roughness of the first surface US1 may be greater than the surface roughness of the second surface US2.

The first area A1 may be an area corresponding to a portion where the agglomeration pattern AP is formed after the first step (S310). The first surface US1 corresponding to the first area A1 may correspond to a surface etched after forming the agglomeration pattern AP. The first surface US1 corresponds to a surface where the agglomeration pattern AP formed by the agglomeration of an indium element is etched, and the first surface US1 may be a surface having greater indium content and higher surface roughness compared to the second surface US2. The second surface US2 does not correspond to a portion where an indium element is agglomerated, and the second surface US2 may have a lower indium content compared to the first surface US1.

In some embodiments, the method may include removing a portion of the top of the preliminary first layer L1-P2 where the agglomeration pattern AP is not formed, as well as removing the agglomeration pattern AP, via etching by the argon (Ar) plasma. Accordingly, the thickness t-I1 of the first layer L1 may be less than the thickness t-I2 of the preliminary first layer L1-P2.

The method may include performing the second step for providing the second plasma to the preliminary first layer L1-P2 for a duration ranging from about 60 seconds to about 200 seconds. If the second step (S320) is performed for less than about 60 seconds, the agglomeration pattern AP may not be sufficiently removed, etching efficiency may be reduced, and the layer quality of the first layer L1 may be deteriorated. If the second step (S320) is performed for longer than about 200 seconds, the process time may be excessively increased, which may decrease process efficiency.

In the second step (S320), the argon (Ar) plasma may have an ion energy of less than about 600 eV. The ion energy of the argon (Ar) plasma may range, for example, from about 150 eV to less than about 600 eV. In some aspects, adjusting the ion energy of the argon (Ar) plasma according to the above range may prevent damage to the first layer L1 (e.g., may prevent a decrease in the film quality of the first layer L1) and secure a high etching selectivity.

FIG. 13B is a graph illustrating the strain rate of a photoresist pattern in accordance with the ion energy of argon plasma. Referring to FIG. 13B, it can be confirmed that at a point where the ion energy of the argon plasma is less than about 600 eV, the change in strain rate (%) of the photoresist is relatively small and less than about 10%, but if the ion energy of the argon plasma increases to about 600 eV or more, the strain rate of the photoresist pattern increases to about 100% or more. Particularly, at a point where the ion energy of the argon plasma is about 700 eV or more, the strain rate of the photoresist pattern increases to about 70% or more, and it is expected that defects such as, for example, damage to the film quality of the first layer L1 may occur. In some embodiments, in the method of manufacturing an electrode of an embodiment, the step of forming a first layer (S300) may include a plurality of first steps (S310) and a plurality of second steps (S320). As in FIG. 11B, the first step (S310) may be performed again after the second step (S320) through a repeating process (CC). The method may include alternately performing the plurality of the first steps (S310) and the plurality of the second steps (S320). In the step of forming the first layer (S300), since the plurality of the first steps (S310) and the plurality of the second steps (S320) are alternately performed, the above-described forming and removing processes of the agglomeration pattern AP may be repeated, which may realize the structure of the first layer L1 (see FIG. 11C) of the first electrode EL1 (see FIG. 11C) to be formed.

In the method of manufacturing an electrode that is included in the display panel of an embodiment, the manufacturing of the first layer formed from the transparent conductive oxide containing indium may include the first step of providing hydrogen (H₂) plasma and the second step of providing argon (Ar) plasma. In the method of manufacturing an electrode of an embodiment, the indium element contained in the transparent conductive oxide is metalized and agglomerated in association with forming an agglomeration pattern in the first step, while the agglomeration pattern is etched by the argon plasma in the second step, thereby improving etching efficiency, preventing the formation of a multilayer film structure, and reducing the process time.

In the conventional method of manufacturing an electrode, during manufacturing of a first layer formed through a transparent conductive oxide, a recovery process is implemented through the injection of oxygen atoms such as, for example, oxygen plasma to suppress the formation of an agglomeration pattern formed by providing hydrogen (H₂) plasma, or the conventional method may include limiting ion flux. Accordingly, for example, the conventional method may result in generated defects which may reduce etching efficiency and significantly deteriorate the layer quality of the first layer due to the formation of a multi-layer structure of an oxide layer, a metalized layer, and an oxide layer. Particularly, in the case of injecting oxygen atoms to suppress the formation of an agglomeration pattern, defects of oxidizing a metal layer provided below the first layer occur, significantly reducing the etching efficiency of the oxidized metal layer, and contamination of the inside of a reaction chamber by oxidized metal particles may occur.

The method of manufacturing an electrode of an embodiment includes the first step in which the formation of the agglomeration pattern by the provision of the hydrogen (H₂) plasma is not suppressed, and the agglomeration pattern is formed through the provision of the hydrogen (H₂) plasma. The method includes the second step in which the agglomeration pattern is removed through the provision of inert gas plasma such as, for example, argon plasma, and the injection process of oxygen atoms may be omitted. Accordingly, for example, the method may be implemented without limiting the ion flux in the etching process. Accordingly, defects due to the impact of limited ion flux on etching efficiency may be prevented, or defects due to the formation of an oxidized metal layer may be prevented, and thus, in the method of manufacturing an electrode of an embodiment, etching efficiency may be improved, and the process time may be reduced.

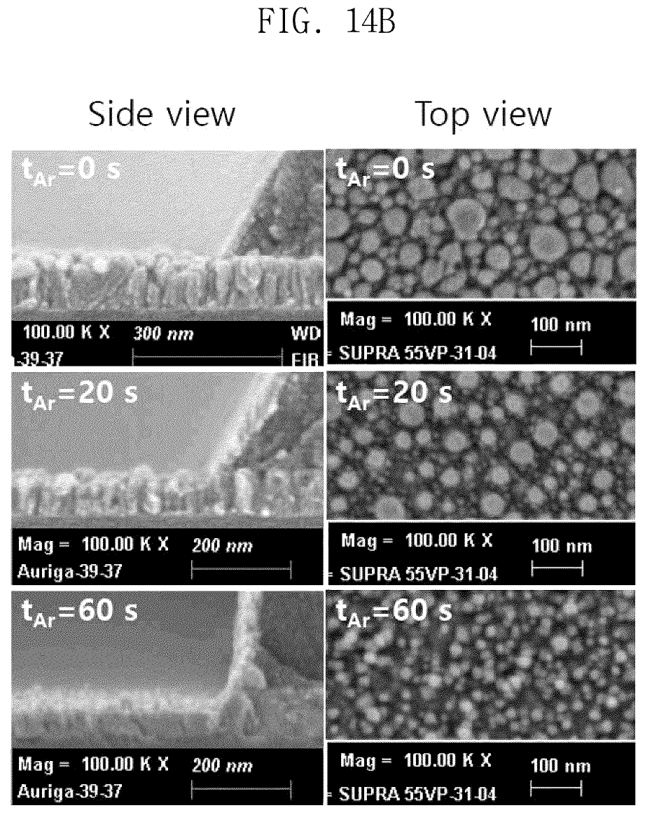

FIG. 14A and FIG. 14B are microscope images illustrating a state of some steps in the method of manufacturing an electrode according to an embodiment supported by the present disclosure. FIG. 14A illustrates cross-sectional microscope images over time and microscope images viewed from the top in the first step (S310 of FIG. 10B) for providing hydrogen (H₂) plasma onto the preliminary first layer in the above-described step of forming the first layer. FIG. 14B illustrates cross-sectional microscope images over time and microscope images viewed from the top in the second step (S320 of FIG. 10B) for providing argon (Ar) plasma onto the preliminary first layer after the first step.

Referring to FIG. 14A, it can be confirmed that in the step (S300 of FIG. 10A) of forming the first layer in the method of manufacturing an electrode of an embodiment, agglomeration patterns are formed on the indium tin oxide in the first step for providing the hydrogen plasma, and as the process time increases, the size of the agglomeration patterns increase. Particularly, in the first step, it can be confirmed that multiple agglomeration patterns were formed after the process time of about 60 seconds, and the size of the agglomeration patterns greatly increased after about 180 seconds.

After that, referring to FIG. 14B, in the step (S300 of FIG. 10A) of forming the first layer in the method of manufacturing an electrode of an embodiment, it can be confirmed that the size of the agglomeration patterns formed on the indium tin oxide gradually decrease in the second step. Particularly, in the second step, it can be confirmed that the size of the agglomeration patterns greatly decreased according to the progress of the process time for about 60 seconds.

In the electrode and the method of manufacturing the same of an embodiment of the present disclosure, a first step of forming an agglomeration pattern through the provision of hydrogen (H₂) plasma and a second step of removing the agglomeration pattern through the provision of argon (Ar) plasma, are included, and thus, etching efficiency may be improved and the processing time may be reduced.

The display panel of an embodiment of the present disclosure includes the electrode manufactured by the manufacturing method and may show excellent manufacturing efficiency and manufacturing reliability.

Although the embodiments of the present invention have been described, it is understood that the present invention should not be limited to the example embodiments, but various changes and modifications can be made by one ordinary skilled in the art within the spirit and scope of the present invention as hereinafter claimed.

What is claimed is:

1. An electrode comprising a first layer comprising a transparent conductive oxide containing indium, wherein:
the first layer comprises a first area and a second area surrounding at least a portion of the first area, and
an indium content of a surface of the first layer corresponding to the first area is greater than an indium content of a surface of the first layer corresponding to the second area.

2. The electrode of claim 1, further comprising a metal layer that is disposed below the first layer and comprises aluminum.

3. The electrode of claim 2, further comprising a second layer that is disposed between the metal layer and the first layer and comprises aluminum oxide.

4. The electrode of claim 1, wherein the transparent conductive oxide comprises indium tin oxide (ITO).

5. The electrode of claim 1, wherein a surface roughness of the surface of the first layer corresponding to the first area is greater than a surface roughness of the surface of the first layer corresponding to the second area.

6. The electrode of claim 1, wherein the first area comprises a plurality of first sub-areas spaced apart from each other.

7. The electrode of claim 6, wherein the second area surrounds each of the plurality of first sub-areas.

8. The electrode of claim 1, wherein the first layer is provided as a single layer composed of the transparent conductive oxide.

9. The electrode of claim 1, wherein a thickness of the first layer ranges from about 2 nm to about 12 nm.

10. A display panel comprising a pixel definition layer in which a light emitting element and a pixel opening are defined, wherein:
the light emitting element comprises a first electrode exposed through the pixel opening, a second electrode disposed on the first electrode, and at least one functional layer disposed between the first electrode and the second electrode,
the first electrode comprises a first layer comprising a transparent conductive oxide containing indium,
a surface of the first layer comprises a first area and a second area surrounding at least a portion of the first area, and
an indium content of the first area is greater than an indium content of the second area.

11. The display panel of claim 10, wherein the first electrode further comprises:
a metal layer that is disposed below the first layer and comprises aluminum; and
a second layer that is disposed between the metal layer and the first layer and comprises aluminum oxide.

12. The display panel of claim 10, wherein the at least one functional layer comprises:
a first emission layer emitting first light; and
a second emission layer disposed on the first emission layer and emitting second light that is different from the first light.

13. The display panel of claim 10, wherein:
the light emitting element comprises a first light emitting element, a second light emitting element, and a third light emitting element, spaced apart in a direction that is perpendicular to a thickness direction, and
the first light emitting element emits red light, the second light emitting element emits green light, and the third light emitting element emits blue light.

14. A method of manufacturing an electrode, the method comprising:
forming a preliminary first layer comprising a transparent conductive oxide containing indium;
forming a photoresist pattern on the preliminary first layer, wherein the photoresist pattern comprises an opening part; and
forming a first layer by etching the preliminary first layer using the photoresist pattern as a mask,
wherein:
the forming of the first layer comprises:
a first step of providing first plasma comprising hydrogen (H₂) plasma on the preliminary first layer; and
a second step of providing second plasma on the preliminary first layer, after the first step,
the indium in the transparent conductive oxide agglomerates by the first plasma and forms an agglomeration pattern in the first step, and
providing the second plasma in the second step etches the agglomeration pattern.

15. The method of manufacturing an electrode of claim 14, wherein each of the first step and the second step is performed in plurality, and the plurality of the first steps and the plurality of the second steps are performed alternately.

16. The method of manufacturing an electrode of claim 14, wherein
a surface of the first layer comprises a first area and a second area surrounding at least a portion of the first area, and
an indium content of the first area is greater than an indium content of the second area.

17. The method of manufacturing an electrode of claim 16, wherein the first area corresponds to an area where the agglomeration pattern is formed in the first step.

18. The method of manufacturing an electrode of claim 14, wherein the first step comprises providing the first plasma for 30 seconds or more.

19. The method of manufacturing an electrode of claim 14, further comprising:
forming a preliminary metal layer comprising aluminum, prior to the forming of the preliminary first layer,
wherein the preliminary first layer is formed on the preliminary metal layer.

20. The method of manufacturing an electrode of claim 19, further comprising:
etching the preliminary metal layer to form a metal layer, wherein the etching of the preliminary metal layer is performed together with the etching of the preliminary first layer to form the first layer.
